(19) United States
(12) Patent Application Publication
(10) Pub. No.: US 2010/0093294 A1
(43) Pub. Date: Apr. 15, 2010

(54) CIRCUIT DEVICE FOR DETECTION AND MOBILE APPARATUS

(76) Inventors: Yoshihide Kanakubo, Kanagawa (JP); Noboru Nakashima, Kanagawa (JP); Kenichi Kurashina, Kanagawa (JP)

Correspondence Address: MCDERMOTT WILL & EMERY LLP, 600 13TH STREET, NW, WASHINGTON, DC, 20005-3096, US

(21) Appl. No.: 12/519,634

(22) PCT Filed: Oct. 15, 2008
(86) PCT No.: PCT/JP2008/002916

§ 371 Date: Jun. 17, 2009

(30) Foreign Application Priority Data
Dec. 7, 2007 (JP) 2007-316651

(51) Int. Cl. H04B 1/18; H03J 5/24

(52) U.S. Cl. 455/182.1; 334/55

(57) ABSTRACT

The circuit device for detection includes: a first terminal 3 and a second terminal 4; a reference terminal 5; a reception frequency tuning section including a first tuning capacitor 6a provided between the first terminal 3 and the reference terminal 5, a second tuning capacitor 6b provided between the second terminal 4 and the reference terminal 5, a first switch 9a connected in series with the first tuning capacitor 6a between the first terminal 3 and the reference terminal 5, and a second switch 9b connected in series with the second tuning capacitor 6b between the second terminal 4 and the reference terminal 5; and a control circuit section including a first control circuit 12a for controlling the operation of the first switch 9a and a second control circuit 12b for controlling the operation of the second switch 9b.

### TECHNICAL FIELD

The present invention relates to a circuit device for detection that tunes a resonant frequency given by a coil serving as a reception antenna and a resonant capacitor using tuning capacitors, and a mobile apparatus provided with the same.

### BACKGROUND ART

In recent years, as mobile apparatuses such as cellular phones, those equipped with a reception function of a contactless communication scheme similar to a contactless IC card and the like have been used. A mobile apparatus, which incorporates a power supply such as a battery, does not need to have electric power transmitted thereto, unlike a contactless IC card, but may only be equipped with a function of detecting a reception signal as the reception function. Such a detection device outputs a reception signal induced by a coil serving as a reception antenna via a resonant circuit including the coil for reception and a capacitor and via a rectifier circuit.

As a conventional detection device, one described in Patent Document 1 is known. FIG. 7 is a circuit diagram showing a configuration of the conventional detection device described in Patent Document 1, which discloses a technique on an energy and data contactless transmission system as will be described below.

As shown in FIG. 7, the conventional detection device includes: a coil 101; a capacitor 102 connected in parallel with the coil 101; a first terminal 103 connected to one end of the coil 101 and one electrode of the capacitor 102; a second terminal 104 connected to the other end of the coil 101 and the other electrode of the capacitor 102; a reference terminal 105; tuning capacitors 106a, 107a, . . . 108a connected in parallel with one another, one electrode of each of which is connected to the first terminal 103; tuning capacitors 106b, 107b, . . . 108b connected in parallel with one another, one electrode of each of which is connected to the second terminal 104; transistors 109a, 110a, . . . 111a respectively provided between the tuning capacitors 106a, 107a, . . . 108a and the reference terminal 105; transistors 109b, 110b, 111b respectively provided between the tuning capacitors 106b, 107b, . . . 108b and the reference terminal 105; a control circuit 112 for supplying a control signal to the gate terminals of the transistors 109a, 110a, . . . 111a, 109b, 110b, . . . 111b; a nonvolatile memory 113 for storing information on the control signal of the control circuit 112; a bridge rectifier circuit 120 connected to the first terminal 103 and the second terminal 104; and a smoothing capacitor 122 provided between an o output terminal 121 and the reference terminal 105.

The gate terminals of the transistors 109a and 109b are connected to each other, and the tuning capacitor 106a and the tuning capacitor 106b have the same capacitance. The tuning capacitors 106a and 106b and the transistors 109a and 109b constitute a pair of tuning elements. Likewise, the gate terminals of the transistors 110a and 110b are connected to each other, and the gate terminals of the transistors 111a and 111b are connected to each other. The tuning capacitors 107a and 107b have the same capacitance, and the tuning capacitors 108a and 108b have the same capacitance. The tuning capacitors 107a and 107b and the transistors 110a and 110b constitute a pair of tuning elements, and the tuning capacitors 108b and 108b and the transistors 111a and 111b constitute a pair of tuning elements.

The bridge rectifier circuit 120 uses the reference terminal 5 as the negative pole for a rectification voltage, and the positive output from the bridge rectifier circuit 120 is outputted via the output terminal 121.

In the conventional contactless transmission system, the coil 101 receives a signal through rough magnetic coupling with a coil for transmission existing outside the detection device, and with this reception, a voltage is generated between the first terminal 3 and the second terminal 4. The voltage generated is rectified by the bridge rectifier circuit 120 and outputted from the output terminal 121 as the detection output. The reception voltage generated between the first terminal 103 and the second terminal 104 will have the largest amplitude when the transmission frequency thereof corresponds with the resonant frequency given by the coil 101 and the capacitor 102. To tune this resonant frequency so as to maximize the detection output, a capacitor pair connected to each other to constitute one tuning element pair are selected from the tuning capacitors 106a, 107a, 108a, 106b, 107b, and 108b. For example, assume that the inductance of the coil 101 is L, the capacitance of the capacitor 102 is C2, and the capacitances of the tuning capacitors 106a and 106b are both C6. When the transistors 109a and 109b are selectively turned ON (brought into conduction) by the control circuit 112, the combined capacitance of the capacitors constituting the resonant circuit will be (C2+C6/2). In this way, the capacitance of the resonant capacitor is adjusted so as to give the maximum amplitude. Also, information on the combination of the capacitor pair to be added to the capacitor 102, i.e., which ones of the transistors 109a to 111a and 109b to 111b are to be turned ON, is stored in the nonvolatile memory 113. Based on the stored information, a signal is sent to the control circuit 112 in the startup process of the apparatus, and the control circuit 112 sets the resonant frequency of the resonant circuit at an appropriate value based on this information.

FIG. 8 is a view showing ideal voltage waveforms A and B generated at the first terminal 103 and the second terminal 104 when the transistors 109a and 109b are ON, for example, as well as an ideal combined voltage waveform C generated at the output terminal 121, in the detection device of FIG. 7. In the contactless transmission system described in Patent Document 1, which is also meant for electric power transmission, the voltage at the output terminal 121 is smoothed by the smoothing capacitor 122 to be supplied as a DC power supply voltage. It should be noted that, since no consideration is herein given to electric power transmission, the waveforms shown are those obtained under the assumption that the smoothing capacitor 122 does not exist or is small in capacitance.

In FIG. 8, A1 denotes the wave height of the voltage waveform A applied to the first terminal 103, B1 denotes the wave height of the voltage waveform B applied to the second terminal 104, and T denotes one period. The voltage waveform A and the voltage waveform B are deviated in phase by 180 degrees from each other, and the voltage waveform A or B whichever is higher appears as the combined voltage waveform C that is the detection output. The amplitudes of the voltage waveforms A and B are ideally equal to each other, and are a half of the absolute value of the maximum of the reception signal (waveform A−waveform B).
Patent Document 1: Japanese Patent Gazette No. 3071468

### DISCLOSURE OF THE INVENTION

### Problems to be Solved by the Invention

However, the conventional configuration has the problem that if there is a difference between the capacitances connected to the first terminal 103 and the second terminal 104 due to variations in the capacitance values of the tuning capacitors 106a and 106b and the like, the detection output waveform may be distorted, causing a malfunction of a reader device due to the waveform detected at the output terminal 121.

FIG. 9 is a waveform diagram showing voltage changes at the first terminal 103, the second terminal 104, and the output terminal 121 occurring when there is a difference in capacitance value due to variations in tuning capacitor and the like in the conventional detection device. Specifically, in FIG. 9, D denotes the voltage waveform at the first terminal 103, E denotes the voltage waveform at the second terminal 104, and F denotes the combined voltage waveform outputted from the output terminal 121. Also, A2 denotes the wave height of the voltage waveform D, B2 denotes the wave height of the voltage waveform E, Δ denotes a difference in the amplitude of the combined voltage waveform, and T denotes one period. Hereinafter, how the difference in amplitude occurs will be described with reference to FIGS. 7, 8 and 9.

In the case of contactless transmission using an air-core coil, the inductance of the coil is 1 to 2 μH. When the transmission frequency is ten and several MHz, a capacitor having a capacitance of about 100 pF is used as the capacitor 102. In contrast to this, the tuning capacitors 106a to 108a and 106b to 108b have a capacitance smaller than several pF, and these capacitors are normally formed inside a semiconductor integrated circuit together with the transistors 109a to 111a and 109b to 111b. For this reason, the variations in the capacitances of the tuning capacitors 106a and 106b will be as high as about ±20% although depending on the fabrication process of the integrated circuit. Since the charging/discharging currents that are generated in the resonant circuit including the coil 101 and the capacitor 102 and flow through the tuning capacitors 106a and 106b are equal to each other, the amplitudes and wave heights of the voltage waveform D at the first terminal 103 and the voltage waveform E at the second terminal 104 are inversely proportional to the capacitances of the corresponding tuning capacitors. If the capacitance of the tuning capacitor 106a is 0.8 times of the capacitance of the tuning capacitor 106b, the wave height A2 of the voltage waveform D will be 1.25 times of the wave height B2 of the voltage waveform E. The voltage waveform D having increased wave height and amplitude is subjected to clamping of its lower-limit value with the potential of the reference terminal 105 through conduction of a negative-side diode of the bridge rectifier circuit 120. At this time, since the voltage waveform E becomes roughly equal to the original reception signal, the distortion of the waveform further deteriorates. Also, there is a possibility that all transistors may be turned OFF (brought out of conduction). In such a case, it will be a series capacitance of a tuning capacitor and the parasitic capacitance of a transistor that is connected to the first terminal 103 or the second terminal 104. This will further increase the voltage variations.

As described above, the capacitance difference between the tuning capacitors causes a difference between the amplitudes of the voltage waveforms at the first terminal 103 and the second terminal 104, and this distorts the detection output waveform. Such a distorted detection waveform may sometimes cause a malfunction of a device for processing or receiving the waveform.

To solve the problem described above, an object of the present invention is to provide a detection device for tuning the resonant frequency given by a coil serving as a reception antenna and a resonant capacitor using tuning capacitors, in which distortion of a detection output waveform is suppressed, and a mobile apparatus provided with such a detection device.

### Means for Solving the Problems

To attain the above object, the circuit device for detection of the present invention is a circuit device for detection used for rectifying a voltage generated between a first terminal and a reference terminal or between a second terminal and the reference terminal by a reception inductor, the device including: the first terminal and the second terminal; the reference terminal; a reception frequency tuning section including: a first tuning capacitor provided between the first terminal and the reference terminal; a second tuning capacitor provided between the second terminal and the reference terminal; a first switch connected in series with the first tuning capacitor between the first terminal and the reference terminal for permitting or prohibiting conduction between the first tuning capacitor and the reference terminal; and a second switch connected in series with the second tuning capacitor between the second terminal and the reference terminal for permitting or prohibiting conduction between the second tuning capacitor and the reference terminal; and a control circuit section including a first control circuit for controlling the operation of the first switch and a second control circuit for controlling the operation of the second switch.

With the above configuration, which permits individual control of the first switch and the second switch, even when the capacitance varies between the tuning capacitors, the resonant frequency of the resonant circuit including the reception inductor and a capacitor can be regulated precisely by turning ON or OFF the first tuning capacitor and the second tuning capacitor as appropriate. Hence, occurrence of a distortion in the detection output waveform can be effectively suppressed. Accordingly, by using the circuit device for detection of the present invention for a mobile apparatus and the like, occurrence of a malfunction of a reader device and the like in a contactless transmission system can be suppressed.

In particular, by providing two capacitors, i.e., the first and second capacitors, connected in series with each other to constitute the resonant circuit and connecting the node between these capacitors to the reference terminal, the first tuning capacitor and the first capacitor are connected in parallel with each other while the second tuning capacitor and the second capacitor are connected in parallel with each other. This can further reduce the influence of variations in the capacitances of the first tuning capacitor and the second tuning capacitor.

The mobile apparatus of the present invention is a mobile apparatus including: a detection circuit device including a radio wave reception section having a reception inductor for receiving a signal to generate a voltage at both ends and a capacitor one electrode of which is connected to one end or the other end of the reception inductor, a reception frequency tuning section for tuning a resonant frequency to the frequency of the signal, a control circuit section for controlling the operation of the reception frequency tuning section, a tuned data storage section for storing information for allowing the control circuit section to control the reception frequency tuning section; and a detection circuit section for receiving the output of the reception frequency tuning section; and a first terminal, a second terminal, and a reference terminal provided for transmission/reception of the signal between the radio wave reception section and the reception frequency tuning section, wherein the reception frequency tuning section includes: a first tuning capacitor provided between the first terminal and the reference terminal; a second tuning capacitor provided between the second terminal and the reference terminal; a first switch connected in series with the first tuning capacitor between the first terminal and the reference terminal for permitting or prohibiting conduction between the first tuning capacitor and the reference terminal; and a second switch connected in series with the second tuning capacitor between the second terminal and the reference terminal for permitting or prohibiting conduction between the second tuning capacitor and the reference terminal, and the control circuit section includes a first control circuit for controlling the operation of the first switch and a second control circuit for controlling the operation of the second switch.

With the above configuration, which permits individual control of the first switch and the second switch, even when the capacitance varies between the tuning capacitors, the resonant frequency of the resonant circuit including the reception inductor and a capacitor can be regulated precisely by turning ON or OFF the first tuning capacitor and the second tuning capacitor as appropriate. Hence, occurrence of a distortion in the detection output waveform can be effectively suppressed. As a result, occurrence of a malfunction of the device and the like during contactless transmission can be suppressed, and hence, communication can be performed further reliably compared with the case of using a conventional mobile apparatus.

### Effect of the Invention

As described above, according to the present invention, in a detection device (circuit device for detection) for tuning the resonant frequency given by a coil serving as a reception antenna and a resonant capacitor using tuning capacitors, variations in tuning capacitor can be absorbed to suppress a distortion in the detection output waveform. Hence, a malfunction of a device for reading the detection can be effectively prevented.

### BRIEF DESCRIPTION OF THE DRAWINGS

FIG. 1(a) is a block diagram of a detection device of Embodiment 1 of the present invention, and FIG. 1(b) is a circuit diagram showing a specific configuration of the detection device.

FIG. 2 is a circuit diagram showing an alteration of the detection device of Embodiment 1.

FIG. 3 is a circuit diagram showing a configuration of a detection device of Embodiment 2 of the present invention.

FIG. 4 is a circuit diagram of a semiconductor integrated circuit including major components of the detection device of the present invention.

FIG. 5 is a circuit diagram showing a configuration of a detection device of Embodiment 3 of the present invention.

FIG. 6 is a block diagram of a mobile apparatus provided with a detection device of Embodiment 4.

FIG. 7 is a circuit diagram showing a configuration of a conventional detection device.

FIG. 8 is a view showing ideal voltage waveforms generated at terminals.

FIG. 9 is a waveform diagram showing voltage changes at a first terminal, a second terminal, and an output terminal occurring when there is a difference between the capacitances of tuning capacitors in the conventional detection device.

### DESCRIPTION OF CHARACTERS

1 Coil
2 Capacitor
2a First capacitor
2b Second capacitor
3 First terminal
4 Second terminal
5 Reference terminal
6a to 8a, 6b to 8b Tuning capacitor
9a to 11a, 9b to 11b Transistor
12a First control circuit
12b Second control circuit
13 Nonvolatile memory
14 Comparator
15 Inverter
16a, 16b Transistor
17, 23a, 23b Diode
20 Bridge rectifier circuit
21a, 21b Output terminal
22 Output capacitor
24a, 24b Negative-side diode
30 Detection device
31 Radio wave reception section
32 Reception frequency tuning section
33 Control circuit section
34 Tuned data storage section
35 Detection circuit section
36 Data processing section
37 Baseband section
38 Memory
39 Mobile apparatus
40 Third terminal

### BEST MODE FOR CARRYING OUT THE INVENTION

### Embodiment 1

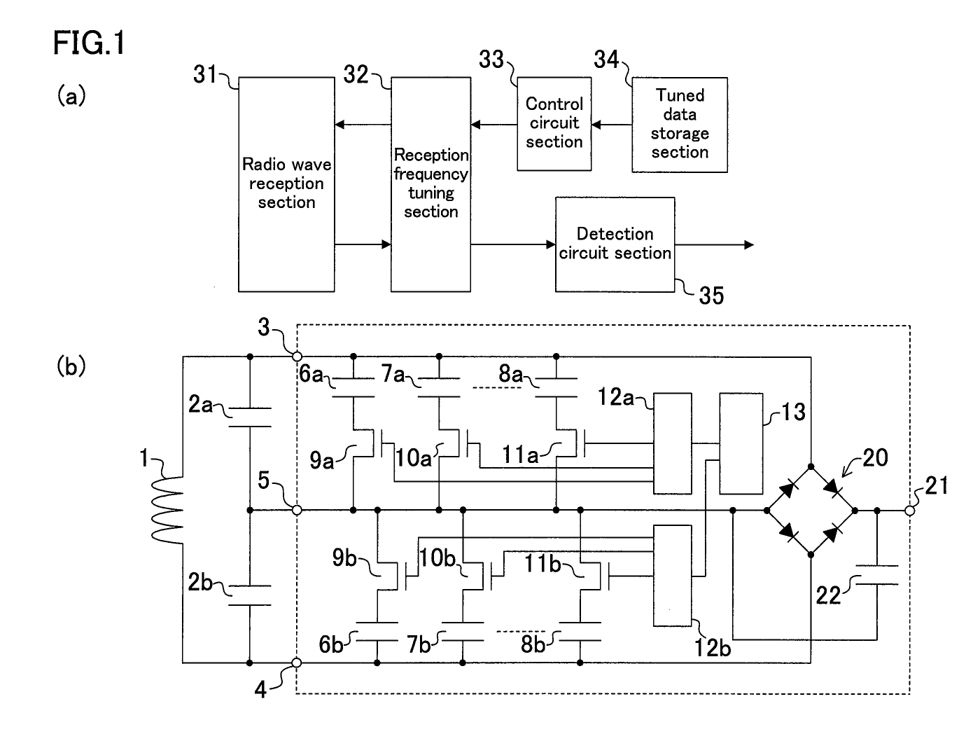

FIG. 1(a) is a block diagram of a detection device (circuit device for detection) of Embodiment 1 of the present invention, and FIG. 1(b) is a circuit diagram showing a specific configuration of the detection device. The detection device of this embodiment is used for a contactless transmission system using magnetism, and in particular, used preferably for a mobile apparatus and the like equipped with power supply. It should be noted that although a contactless transmission system includes a circuit for transmitting data and an evaluation circuit and the like connected downstream of the transmission circuit, only a configuration for tuning the resonant frequency of a resonant circuit will be herein described. Hereinafter, the detection device of this embodiment will be described in detail.

First, as shown in FIG. 1(a), the detection device of this embodiment includes: a radio wave reception section 31 for receiving a signal from an external apparatus and the like; a reception frequency tuning section 32 for tuning the resonant frequency to the frequency of the reception signal; a control circuit section 33 for controlling the reception frequency tuning section 32; a tuned data storage section 34 for holding control information to be supplied to the control circuit section 33; and a detection circuit section 35 for outputting the detection result in response to the output of the reception frequency tuning section 32.

As shown in FIG. 1(b), the radio wave reception section 31 includes: a coil (reception inductor) 1; a first capacitor 2a one of electrodes of which is connected to one end of the coil 1; and a second capacitor 2b one of electrodes of which is connected to the other end of the coil 1 and the other electrode of which is connected to the first capacitor 2a. Between the radio wave reception section 31 and the reception frequency tuning section 32, provided are a reference terminal 5 and a first terminal 3 and a second terminal 4 for transmitting/receiving a signal. The first terminal 3 is connected to one end of the coil 1 and one electrode of the first capacitor 2a, and the second terminal 4 is connected to the other end of the coil 1 and one electrode of the second capacitor 2b. The reference terminal 5 is connected to the other electrode of the first capacitor 2a and the other electrode of the second capacitor 2b.

The reception frequency tuning section 32 includes: tuning capacitors 6a, 7a, . . . 8a provided between the first terminal 3 and the reference terminal 5 to be connected in parallel with one another; tuning capacitors 6b, 7b, . . . 8b provided between the second terminal 4 and the reference terminal 5 to be connected in parallel with one another; transistors (first switches) 9a, 10a, . . . 11 a respectively provided between the tuning capacitors 6a, 7a, . . . 8a and the reference terminal 5 to permit or prohibit conduction between the tuning capacitors 6a, 7a, . . . 8a and the reference terminal 5; and transistors (second switches) 9b, 10b, . . . 11b to permit or prohibit conduction between the tuning capacitors 6b, 7b, . . . 8b and the reference terminal 5. The tuning capacitors 6a, 7a, . . . 8a are connected in parallel with the first capacitor 2a, and the tuning capacitors 6b, 7b, . . . 8b are connected in parallel with the second capacitor 2b. The number of capacitor pairs each including a tuning capacitor provided between the first terminal 3 and the reference terminal 5 and a tuning capacitor provided between the second terminal 4 and the reference terminal 5 and designed to have the same capacitance as the counterpart tuning capacitor, is not limited specifically, but may be set arbitrarily. The tuning capacitors 6a and 6b, the tuning capacitors 7a and 7b, and the tuning capacitors 8a and 8b respectively have the same capacitances.

The control circuit section 33 includes: a first control circuit 12a for controlling the operation of the transistors 9a, 10a and 11a individually; and a second control circuit 12b for controlling the operation of the transistors 9b, 10b and 11b individually.

The tuned data storage section 34 includes a nonvolatile memory 13 for storing information on which ones of the transistors 9a to 11a and 9b to 11b should be turned ON. The information is supplied to the first control circuit 12a and the second control circuit 12b. The transistor control information may be stored in advance, or may be received from outside the detection device. As the nonvolatile memory 13, a ROM writable after fabrication of the detection circuit, an FeRAM, an MRAM, a MONOS and the like may be used. In the case of supplying control information from outside the detection device, a latch circuit, a DRAM, and the like may be used in place of the nonvolatile memory 13.

The detection circuit section 35 includes: an output terminal 21, an output capacitor 22 provided between the reference terminal 5 and the output terminal 21; and a bridge rectifier circuit 20 provided between the first and second terminals 3 and 4 and the output terminal 21. The output terminal 21, which is also the output terminal of the detection device, serves as the positive pole for the bridge rectification voltage. The reference terminal 5 serves as the negative pole for the rectification voltage. The bridge rectifier circuit 20 includes: a first diode whose anode is connected to the first terminal 3 and whose cathode is connected to the output terminal 21; a second diode whose anode is connected to the second terminal 4 and whose cathode is connected to the output terminal 21; a third diode whose anode is connected to the reference terminal 5 and whose cathode is connected to the anode of the first diode and the first terminal 3; and a fourth diode whose anode is connected to the reference terminal 5 and whose cathode is connected to the anode of the second diode and the second terminal 4. The output capacitor 22 is provided for smoothing the detection output, which may be omitted depending on the circuit configuration.

In the example shown in FIG. 1(b), the reception frequency tuning section 32, the control circuit section 33, the tuned data storage section 34, the detection circuit section 35, the first terminal 3, the second terminal 4, the reference terminal 5, and the output terminal 21 are integrated on the same semiconductor substrate (shown by the broken line in FIG. 1(b)). Note however that the detection circuit section 35, the tuned data storage section 34, and the like may be placed on a substrate different from the semiconductor substrate on which the reception frequency tuning section 32 is placed.

The capacitances of the tuning capacitors 6a, 7a, 8a, 6b, 7b, and 8b are considerably small compared with the capacitances of the first capacitor 2a and the second capacitor 2b.

The operation of the detection device configured as described above will be described.

In the detection device of this embodiment, the coil 1 receives a signal through rough magnetic coupling with a coil for transmission existing outside the detection device. With this signal reception, a voltage is generated between the first terminal 3 and the second terminal 4. The voltage generated between the terminals is rectified by the bridge rectifier circuit 20 and outputted from the output terminal 21 as the detection output. The frequency of the reception signal is about 13.56 MHz to 14 MHz, for example. The reception voltage generated between the first terminal 3 and the second terminal 4 will have the largest amplitude when the frequency of the reception signal corresponds with the resonant frequency of a resonant circuit including the coil 1, the first capacitor 2a, and the second capacitor 2b. To tune this resonant frequency so as to maximize the detection output, a pair of capacitors to be connected to the resonant circuit are selected from the tuning capacitors 6a to 8a and 6b to 8b. For example, assume that the inductance of the coil 1 is L, the capacitances of the first capacitor 2a and the second capacitor 2b are both C2, and the capacitances of the tuning capacitors 6a and 6b are both C6. When the transistors 9a and 9b are turned ON by the first control circuit 12a and the second control circuit 12b, the tuning capacitor 6a is in parallel connection with the first capacitor 2a, and the tuning capacitor 6b is in parallel connection with the second capacitor 2b. Hence, the combined capacitance of the capacitors constituting the resonant circuit is (C2+C6)/2. In this way, the capacitance of the resonant capacitors is adjusted so as to obtain the maximum amplitude. Also, information on the combination of capacitors added to the first capacitor 2a and the second capacitor 2b, i.e., which ones of the transistors 9a to 11a and 9b to 11b are to be turned ON, is stored in the nonvolatile memory 13 as described above. Based on the stored information, the tuned data storage section 34 transmits a signal to the first control circuit 12a and the second control circuit 12b in the startup process of the apparatus, so that the resonant frequency of the resonant circuit is set to an appropriate value.

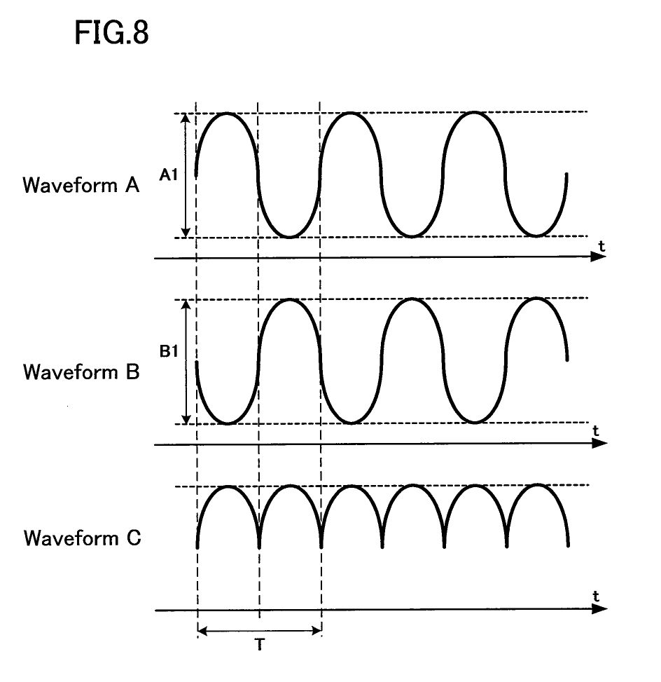

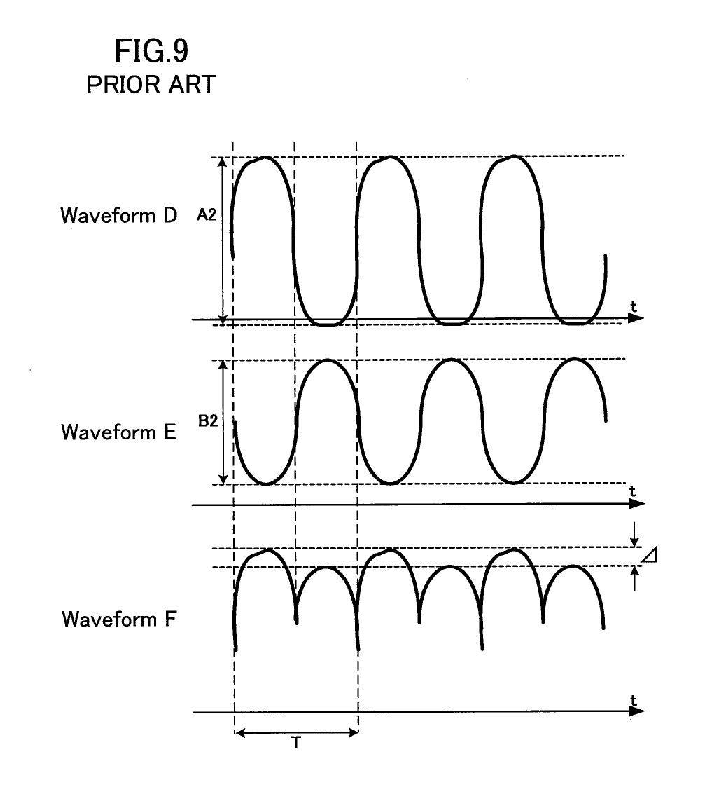

In the detection device of this embodiment shown in FIG. 1(b), the voltage waveforms generated at the first terminal 3, the second terminal 4, and the output terminal 21 are ideally like the waveforms A, B, and C shown in FIG. 8, as in the conventional detection device. That is, the voltage waveform A at the first terminal 3 and the voltage waveform B at the second terminal 4 are different in phase by 180 degrees from each other and have the same wave height (A1=B1). The voltage waveform A or B whichever is higher appears as the combined voltage waveform C that is generated at the output terminal 21. The amplitudes of the voltage waveforms A and B are ideally equal to each other, and are a half of the absolute value of the maximum of the reception signal (waveform A−waveform B).

Next, the waveforms observed when the capacitances of the tuning capacitors vary will be described. For example, when the inductance of the coil 1 is 1 to 2 μH and the transmission frequency of the reception signal is ten and several MHz, a capacitor having a capacitance of about 200 pF is used as the first capacitor 2a and the second capacitor 2b individually since the first and second capacitors 2a and 2b are connected in series with each other. In contrast to this, the tuning capacitors 6a to 8a and 6b to 8b have a capacitance not more than several pF and are often formed inside a semiconductor integrated circuit together with the transistors 9a to 11a and 9b to 11b. For this reason, the variations in the capacitances of the tuning capacitors will be as high as about ±20% although depending on the fabrication process of the integrated circuit. For example, assume that only the transistors 9a and 9b are ON, the capacitances of the first and second capacitors 2a and 2b are both 200 pF, the capacitance of the tuning capacitor 6a is 4 pF, and the capacitance of the tuning capacitor 6b is 5 pF. In this case, while the parallel capacitance of the first capacitor 2a and the tuning capacitor 6a, 204 pF, is connected between the first terminal 3 and the reference terminal 5, the parallel capacitance of the second capacitor 2b and the tuning capacitor 6b, 205 pF, is connected between the second terminal 4 and the reference terminal 5. This difference in capacitance is minute compared with the capacitance of the resonant circuit. Since the first capacitor 2a and the second capacitor 2b are provided separately from the integrated circuit, variations in the capacitances of these capacitors can be suppressed greatly compared with those of the tuning capacitors. Hence, in the detection device of this embodiment, since the capacitances of the first and second capacitors 2a and 2b are far greater than and dominant over those of the tuning capacitors, and the capacitance difference between the first capacitor 2a and the second capacitor 2b is minute, the variations in tuning capacitor are absorbed. As a result, the difference in amplitude between the waveform at the first terminal 3 and the waveform at the second terminal 4 is only about 0.002%, hardly causing a distortion in the detection waveform at the output terminal 21. Hence, the waveforms at the first terminal 3, the second terminal 4, and the output terminal 21 in the detection device of this embodiment are roughly like the ideal waveforms A, B, and C shown in FIG. 8. Accordingly, in a mobile apparatus such as a cellular phone and a personal digital assistant (PDA) equipped with the detection device of this embodiment, desired information communication can be performed without occurrence of a malfunction of an information reader device and the like.

In this embodiment, also, the transistors 9a to 11a and the transistors 9b to 11b can be individually turned ON/OFF.

With the above configuration, variations in the capacitances of the first capacitor 2a and the second capacitor 2b can also be adjusted. For example, when the capacitance of the first capacitor 2a is 200 pF and the capacitance of the second capacitor 2b is 204 pF, the transistor 9a and the transistor 9b may be turned ON and OFF, respectively, so that a capacitance of 204 pF will be connected to both the first terminal 3 and the second terminal 4. In this case, tuning of the resonant frequency can be performed using other tuning capacitors, and this almost eliminates the difference in amplitude between the waveforms at the first terminal 3 and the second terminal 4. Hence, occurrence of a distortion in the detection waveform is suppressed.

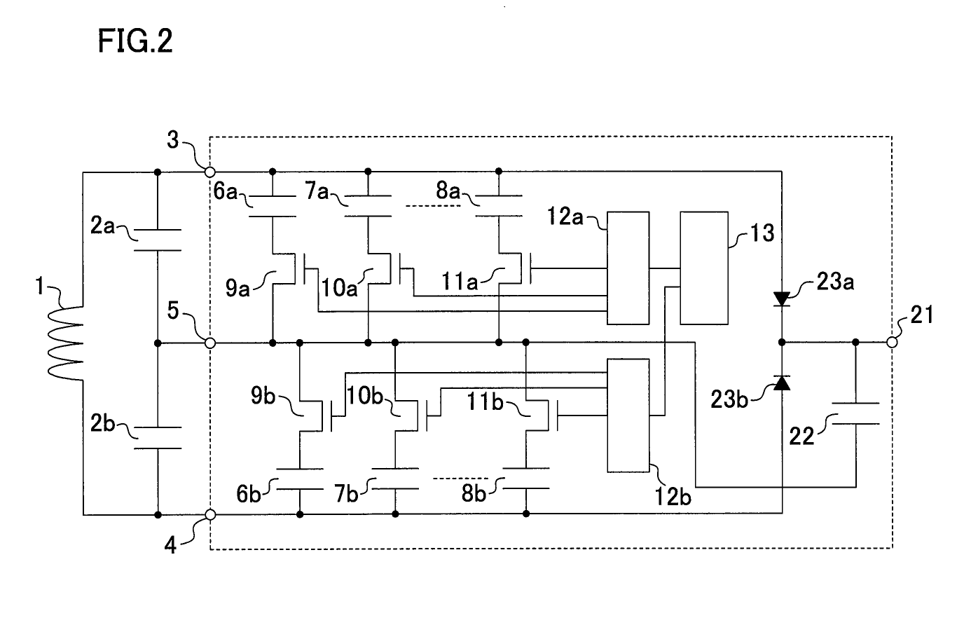

In the detection device of this embodiment, the voltage changes occurring at the first terminal 3 and the second terminal 4 provide waveforms having phases inverted 180° from each other and the same amplitude. The bottom points of these voltage waveforms are equal to or more than the potential of the reference terminal 5, and hence, the two negative-side diodes connected to the reference terminal 5 in the bridge rectifier circuit 20 shown in FIG. 1 will not be ON during steady-state operation. Accordingly, a configuration as shown in FIG. 2 may also be adopted without causing any problem.

FIG. 2 is a circuit diagram showing an alteration of the detection device of this embodiment. In the detection device of this alteration, two diodes whose anodes are connected to the reference terminal 5 are omitted from the bridge rectifier circuit 20 shown in FIG. 1 (see FIG. 1(b)).

However, the configuration having the bridge rectifier circuit 20 is desired to ensure that the voltages at the first terminal 3 and the second terminal 4 are prevented from becoming a negative potential even when the amplitude of the reception waveform varies during startup and in a transient state in which the positional relationship between the coil for reception and the coil for transmission changes.

In the detection device of this embodiment, the first capacitor 2a and the second capacitor 2b can be integrated on the same semiconductor substrate as the reception frequency tuning section 32, the control circuit section 33, and the like. In this case, the variations in the capacitances of the first and second capacitors 2a and 2b may increase compared with the case of forming these capacitors separately from the integrated circuit. However, with the individual control of the transistors 9a, 10a, . . . 11a and the transistors 9b, 10b, . . . 11b, the variations in capacitance can be reduced. Hence, by placing the first and second capacitors 2a and 2b inside the integrated circuit, the mounted area of the detection device can be widely reduced compared with the case of placing the capacitors outside the integrated circuit.

In the reception frequency tuning section 32, when a plurality of tuning capacitors are connected to the first terminal 3, the capacitances of the tuning capacitors may be equal to each other or may be different from each other as appropriate. This also applies to tuning capacitors connected to the second terminal 4.

### Embodiment 2

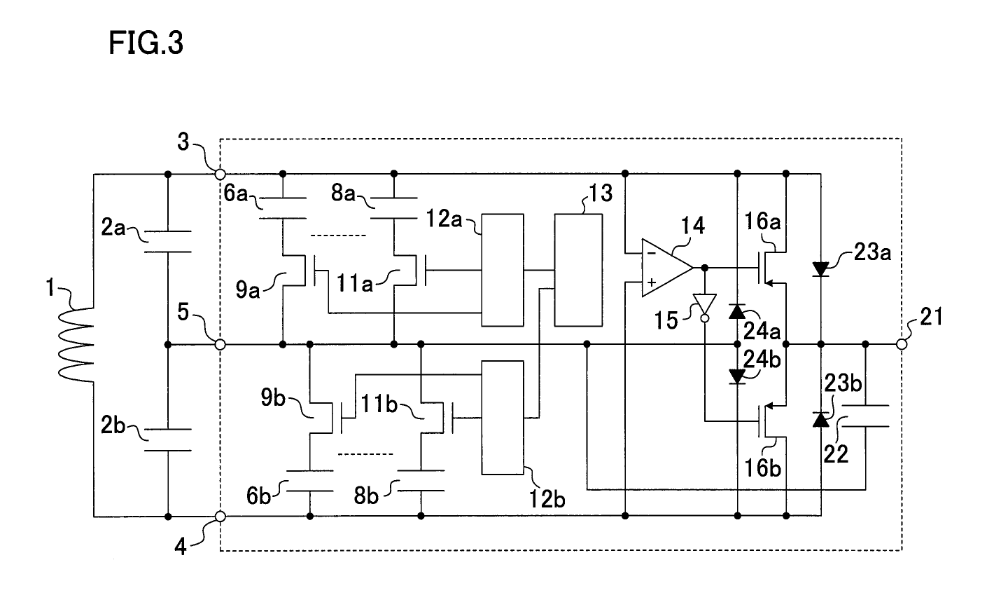

FIG. 3 is a circuit diagram showing a configuration of the detection device of Embodiment 2 of the present invention.

The detection device of this embodiment is different from the detection device of Embodiment 1 shown in FIG. 1 in that the bridge rectifier circuit 20 of the detection circuit section additionally includes: a comparator 14 for comparing the potentials of the first terminal 3 and the second terminal 4 with each other; an inverter 15 for inverting the output of the comparator 14; a transistor 16a for short-circuiting the anode and cathode of the diode 23a under the control with the output of the comparator 14; and a transistor 16b for short-circuiting the anode and cathode of the diode 23b under the control with the output of the inverter 15.

In other words, a feature of the detection device of this embodiment is that the positive-side rectifier circuit is configured as a synchronous rectifier circuit with respect to negative-side diodes 24a and 24b that are ON only during transition when the reception state changes and are not ON during steady-state operation. The other configuration is similar to the detection device of Embodiment 1.

In the detection device of this embodiment, the transistor 16a connected in parallel with the diode 23a is ON when the voltage at the first terminal 3 is higher than the voltage at the second terminal 4, and the transistor 16b connected in parallel with the diode 23b is ON when the voltage at the second terminal 4 is higher than the voltage at the first terminal 3. Since a voltage drop caused by ON resistance of a transistor is small compared with a voltage drop caused by a diode, this configuration suppresses a forward voltage drop in the positive-side rectifier circuit, and hence can increase the level of the detection output.

In the detection devices of Embodiments 1 and 2, the capacitance difference due to variations in tuning capacitor was described as occurring because the tuning capacitors were formed in the same semiconductor integrated circuit as the transistors. However, the detection device of the present invention is not limited to the configurations described above. Even in the case of placing variation-suppressed tuning capacitors outside the integrated circuit, there is a possibility that all transistors may become OFF unexpectedly to during operation. In such a case, it will be a series capacitance of a tuning capacitor and the parasitic capacitance of a transistor that is connected to the first terminal 3 and the second terminal 4, and this will further increase the variations in capacitance. Hence, the configurations of the present invention provide an effect of suppressing distortion in detection waveform irrespective of whether the tuning capacitors are placed inside or outside the integrated circuit, and hence can effectively suppress occurrence of a malfunction and the like in a contactless transmission system.

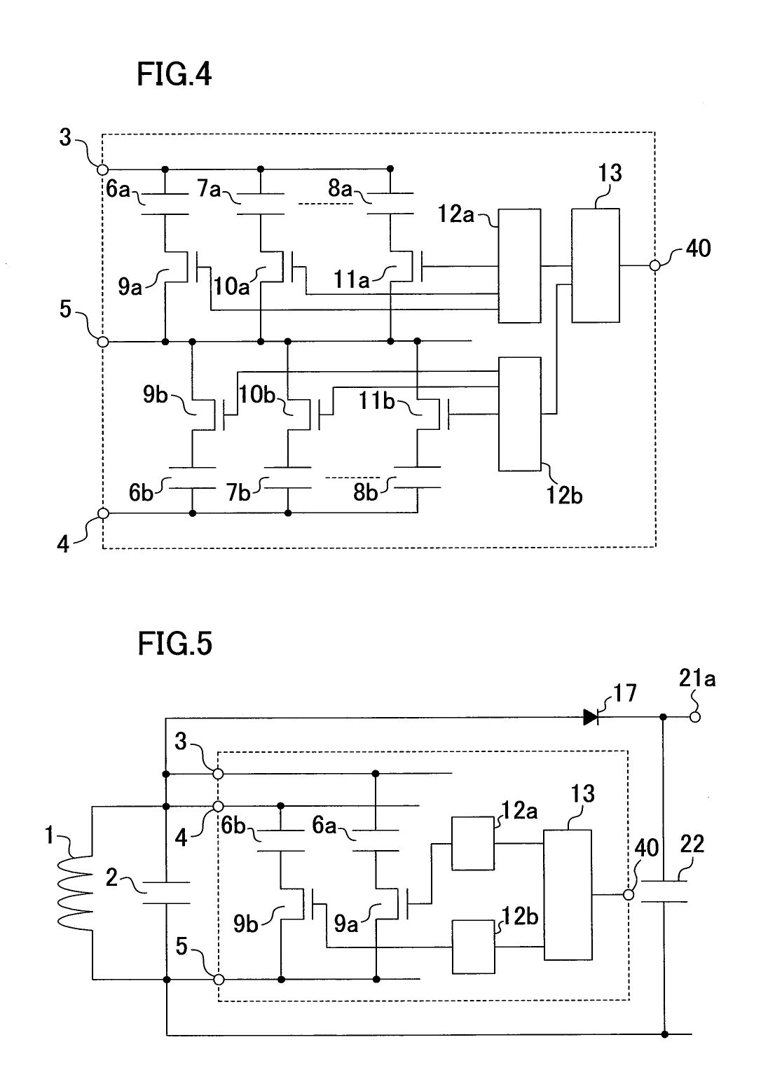

Also, by forming major components of the detection device of the present invention on the same semiconductor substrate as one integrated circuit, the convenience of the device is facilitated. For example, as shown in FIG. 4, the tuning capacitors 6a to 8a and 6b to 8b, the transistors 9a to 11a and 9b to 11b, the first control circuit 12a, the second control circuit 12b, and the nonvolatile memory 13 are formed as one semiconductor integrated circuit. The first terminal 3 serves as the junction point between the tuning capacitors 6a to 8a and the radio wave reception section, and the second terminal 4 serves as the junction point between the tuning capacitors 6b to 8b and the radio wave reception section. A third terminal 40 is a terminal for receiving transistor control information from outside.

As mentioned earlier, the numbers of tuning capacitors and transistors corresponding to the tuning capacitors are not limited. By increasing the number of the tuning elements, wider-range regulation, or fine-tuning, of the capacitance can be achieved. This makes it easy to respond to a change in the reception state of the detection device, switching of the communication frequency, and the like.

### Embodiment 3

FIG. 5 is a circuit diagram showing a configuration of a detection device of Embodiment 3 of the present invention. While the detection devices of Embodiments 1 and 2 perform full-wave rectification for the reception signal, the detection device of this embodiment performs half-wave rectification.

In the detection device of this embodiment, the first terminal 3 serves as the junction point between the tuning capacitors 6a to 8a and the radio wave reception section, and the second terminal 4 serves as the junction point between the tuning capacitors 6b to 8b and the radio wave reception section.

Specifically, in the detection device of this embodiment, a non-divided capacitor 2 constitutes a resonant circuit together with the coil 1, and the first terminal 3 and the second terminal 4 are connected to the same end (one end) of the coil 1 and the same electrode (one electrode) of the capacitor 2. The reference terminal 5 is connected to the other end of the coil 1 and the other electrode of the capacitor 2. The tuning capacitors 6a and 6b are designed to have the same capacitance and are both connected in parallel with the capacitor 2. The transistor 9a is provided between the tuning capacitor 6a and the reference terminal 5, and the transistor 9b is provided between the tuning capacitor 6b and the reference terminal 5. The operations of the transistor 9a and the transistor 9b are individually controlled by the first control circuit 12a and the second control circuit 12b, respectively. The anode of a diode 17 is connected to the coil 1, the capacitor 2, the first terminal 3, and the second terminal 4, and the cathode thereof is connected to an output terminal 21a and the output capacitor 22. The nonvolatile memory 13 is connected to the third terminal 40.

With the above configuration, also, in which the transistors 9a and 9b can be individually controlled, the variations in the capacitances of the tuning capacitors 6a and 6b can be suppressed.

In the detection device of this embodiment, also, the convenience can be facilitated by integrating the tuning capacitors 6a and 6b, the transistors 9a and 9b, the first control circuit 12a, the second control circuit 12b, the nonvolatile memory, and the like on the same semiconductor substrate.

In the integrated circuit, the numbers of tuning capacitors connected to the first terminal 3 and tuning capacitors connected to the second terminal 4 are not specifically limited.

### Embodiment 4

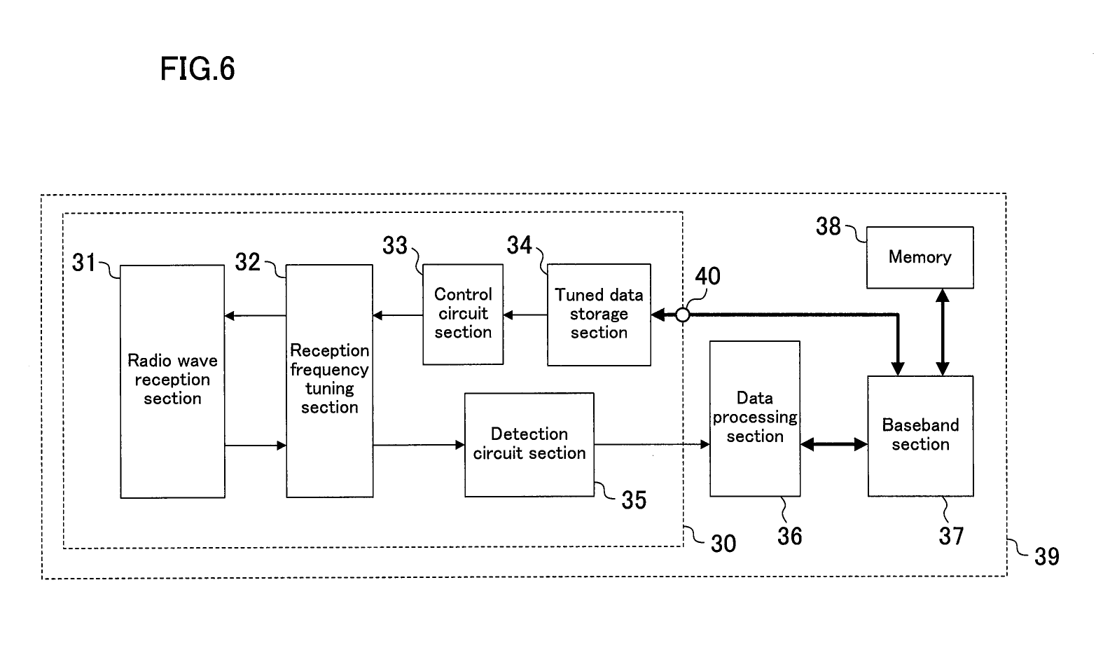

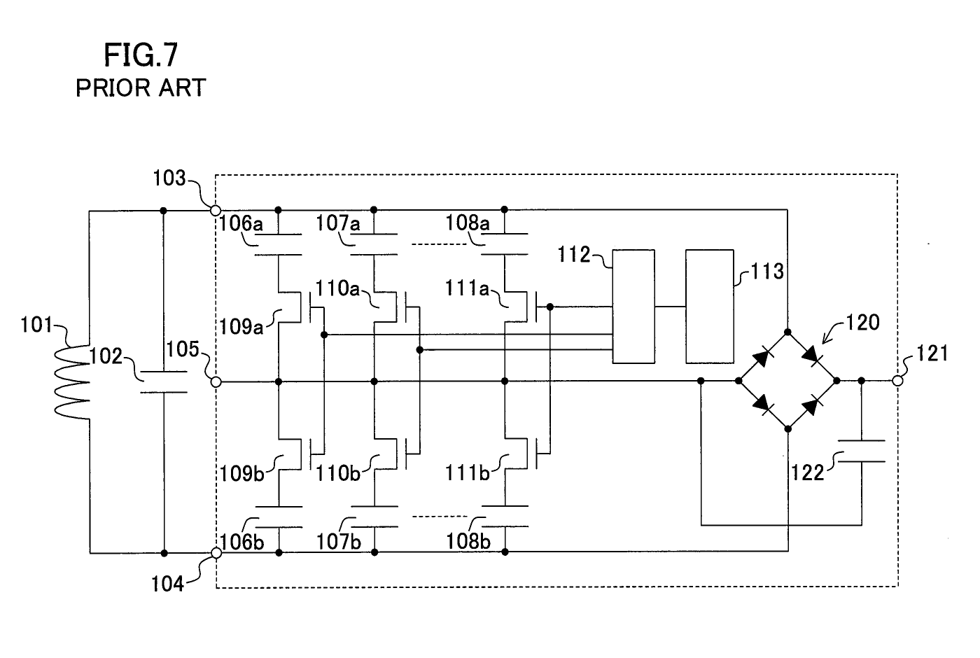

As Embodiment 4 of the present invention, a configuration of a mobile apparatus equipped with the detection device of the present invention will be described. FIG. 6 is a block diagram of a mobile apparatus provided with the detection device of Embodiment 4. In this embodiment, a mobile apparatus including the detection device shown in FIG. 1(a) described in Embodiment 1 will be described.

As shown in FIG. 6, the mobile apparatus 39 of this embodiment includes: a detection device 30; a data processing section 36 for processing a signal outputted from the detection device 30; a baseband section 37 for performing bidirectional communication with the data processing section 36; and a memory 38 as a storage device.

The detection device 30 includes the radio wave reception section 31, the reception frequency tuning section 32, the control circuit section 33, the tuned data storage section 34, and the detection circuit section 35.

In the mobile apparatus of FIG. 6, an output signal from the tuned data storage section 34 is inputted into the control circuit section 33, a control signal from the control circuit section 33 is inputted into the reception frequency tuning section 32, and an output signal from the reception frequency tuning section 32 is inputted into the radio wave reception section 31. Also, an output signal from the radio wave reception section 31 is inputted into the detection circuit section 35 via the reception frequency tuning section 32, and an output signal from the detection circuit section 35 is inputted into the data processing section 36.

In the radio wave reception section 31, which corresponds to the coil 1 for reception, the first capacitor 2a, and the second capacitor 2b shown in FIG. 1, the coil for reception receives a signal through rough magnetic coupling with a coil for transmission outside. The reception signal generated in the radio wave reception section 31 is outputted as the detection output via the reception frequency tuning section 32 and the detection circuit section 35.

The reception frequency tuning section 32 corresponds to the tuning capacitors 6a to 8a and 6b to 8b and the transistors 9a to 11a and 9b to lib shown in FIG. 1, and the detection circuit section 35 corresponds to the bridge rectifier circuit 20 and the output capacitor 22 shown in FIG. 1. The detection output from the detection circuit section 35 is inputted into the data processing section 36 and converted to a logic signal by the data processing section 36. The logic signal is then sent to the baseband section 37. At this stage, a signal indicating execution of frequency tuning is sent from the baseband section 37 to the tuned data storage section 34 for tuning the resonant frequency in the radio wave reception section 31 so as to maximize the detection output. The data stored in the tuned data storage section 34 is information on which ones of the tuning capacitors in the reception frequency tuning section 32 should be connected to the radio wave reception section 31 by the control circuit section 33. Specifically, the control circuit section 33 corresponds to the first control circuit 12a and the second control circuit 12b, and the tuned data storage section 34 corresponds to the nonvolatile memory 13. Note however that in the mobile apparatus of this embodiment, in which control information is written into the tuned data storage section 34 from the baseband section 37 via the third terminal 40 during operation, the tuned data storage section 34 may include a volatile memory such as a latch circuit for storing control information temporarily, a DRAM, and the like. In this case, integration is easy compared with the case of using a nonvolatile memory, and hence the fabrication cost can be reduced.

The resonant frequency in the radio wave reception section 31 is tuned in the reception frequency tuning section 32, and the detection output from the detection circuit section 35 is sent to the data processing section 36. The data processing section 36 processes the data to a logic signal and sends the logic signal to the baseband section 37. The baseband section 37 sends a signal for frequency tuning to the tuned data storage section 34, so that the operation of frequency tuning as described above is performed repeatedly, until the frequency is set to a value with which the detection output level is appropriate.

Once the resonant frequency in the radio wave reception section 31 becomes an appropriate frequency, the tuned data is stored in the tuned data storage section 34. The tuned data storage section 34 sends a control signal to the control circuit section 33 based on the stored information in the startup process of the mobile apparatus 39, so that the resonant frequency in the radio wave reception section 31 is set to an appropriate value every time the startup process is performed. With the tuned data storage section 34 storing a once-tuned value, it is unnecessary to perform the frequency tuning operation in the startup process. Note that similar operation to that described above will also be performed when the tuned data storage section 34 includes a volatile memory such as a latch circuit.

The mobile apparatus of this embodiment, which uses a detection device absorbing variations in tuning capacitor to thereby suppress a distortion in the detection output waveform, can suppress occurrence of a malfunction during communication and hence can perform contactless data communication more reliably.

The detection device in this embodiment may have any of the configurations described in Embodiments 1 to 3.

### INDUSTRIAL APPLICABILITY

The present invention is useful for terminal apparatuses and the like equipped with a reception function of a contactless communication scheme.

1. A circuit device for detection used for rectifying a voltage generated between a first terminal and a reference terminal or between a second terminal and the reference terminal by a reception inductor, the device comprising:
the first terminal and the second terminal;
the reference terminal;
a reception frequency tuning section including: a first tuning capacitor provided between the first terminal and the reference terminal; a second tuning capacitor provided between the second terminal and the reference terminal; a first switch connected in series with the first tuning capacitor between the first terminal and the reference terminal for permitting or prohibiting conduction between the first tuning capacitor and the reference terminal; and a second switch connected in series with the second tuning capacitor between the second terminal and the reference terminal for permitting or prohibiting conduction between the second tuning capacitor and the reference terminal; and
a control circuit section including a first control circuit for controlling the operation of the first switch and a second control circuit for controlling the operation of the second switch.

2. The circuit device for detection of claim 1, wherein the first tuning capacitor comprises n first tuning capacitors where n is an integer equal to or more than 2, and the first tuning capacitors are connected in parallel with each other,
the first switch comprises n first switches corresponding to the n first tuning capacitors, and the first switches are connected in parallel with each other,
the first control circuit controls the operation of the n first switches individually, and
the second control circuit controls the operation of the n second switches individually.

3. The circuit device for detection of claim 2, further comprising a tuned data storage section including a data storage portion for storing first information on which one of the n first switches should be turned ON or OFF and second information on which one of the n second switches should be turned ON or OFF.

4. The circuit device for detection of claim 3, wherein the data storage portion includes a latch circuit.

5. The circuit device for detection of claim 3, wherein the data storage portion includes a nonvolatile memory.

6. The circuit device for detection of claim 1, wherein at least the first tuning capacitor, the second tuning capacitor, the first switch, the second switch, the first control circuit, and the second control circuit are integrated on a same semiconductor substrate.

7. The circuit device for detection of claim 1, further comprising a radio wave reception section including:
the reception inductor for receiving a signal to generate a voltage at both ends, one of the ends being connected to the first terminal and the other end being connected to the second terminal;
a first capacitor one electrode of which is connected to one end of the reception inductor and the first terminal and the other electrode of which is connected to the reference terminal, the first capacitor being connected in parallel with the first tuning capacitor; and
a second capacitor one electrode of which is connected to the other end of the reception inductor and the second terminal and the other electrode of which is connected to the reference terminal, the second capacitor being connected in parallel with the second tuning capacitor.

8. The circuit device for detection of claim 7, wherein the first capacitor and the second capacitor are provided outside a substrate on which the first tuning capacitor and the second tuning capacitor are provided.

9. The circuit device for detection of claim 7, wherein the capacitances of the first tuning capacitor and the second tuning capacitor are smaller than the capacitances of the first capacitor and the second capacitor.

10. The circuit device for detection of claim 1, further comprising a detection circuit section including: an output portion; a first diode whose anode is connected to the first terminal and whose cathode is connected to the output portion; and a second diode whose anode is connected to the second terminal and whose cathode is connected to the output portion.

11. The circuit device for detection of claim 10, wherein the detection circuit section further includes: a third diode whose anode is connected to the reference terminal and whose cathode is connected to the anode of the first diode and the first terminal; and a fourth diode whose anode is connected to the reference terminal and whose cathode is connected to the anode of the second diode and the second terminal, and
the first diode, the second diode, the third diode, and the fourth diode constitute a bridge rectifier circuit.

12. The circuit device for detection of claim 11, wherein the detection circuit section further includes: a comparator for comparing the potential of the first terminal with the potential of the second terminal; a third switch controlled with the output of the comparator for short-circuiting the anode and cathode of the first diode; and a fourth switch controlled with an inverted signal of the output of the comparator for short-circuiting the anode and cathode of the second diode.

13. The circuit device for detection of claim 1, further comprising a radio wave reception section including:
the reception inductor for receiving a signal to generate a voltage at both ends, one of the ends being connected to the first terminal and the second terminal and the other end being connected to the reference terminal; and
a capacitor one electrode of which is connected to one end of the reception inductor, the first terminal, and the second terminal, and the other electrode of which is connected to the reference terminal and the other end of the reception inductor, the capacitor being connected in parallel with the first tuning capacitor and the second tuning capacitor.

14. A mobile apparatus comprising:
a detection circuit device including a radio wave reception section having a reception inductor for receiving a signal to generate a voltage at both ends and a capacitor one electrode of which is connected to one end or the other end of the reception inductor, a reception frequency tuning section for tuning a resonant frequency to the frequency of the signal, a control circuit section for controlling the operation of the reception frequency tuning section, a tuned data storage section for storing information for allowing the control circuit section to control the reception frequency tuning section; and a detection circuit section for receiving the output of the reception frequency tuning section; and a first terminal, a second terminal, and a reference terminal provided for transmission/reception of the signal between the radio wave reception section and the reception frequency tuning section,
wherein the reception frequency tuning section includes: a first tuning capacitor provided between the first terminal and the reference terminal; a second tuning capacitor provided between the second terminal and the reference terminal; a first switch connected in series with the first tuning capacitor between the first terminal and the reference terminal for permitting or prohibiting conduction between the first tuning capacitor and the reference terminal; and a second switch connected in series with the second tuning capacitor between the second terminal and the reference terminal for permitting or prohibiting conduction between the second tuning capacitor and the reference terminal, and
the control circuit section includes a first control circuit for controlling the operation of the first switch and a second control circuit for controlling the operation of the second switch.

15. The mobile apparatus of claim 14, wherein a number of multiple ones of the first tuning capacitor is n where n is an integer equal to or more than 2, and the first tuning capacitors are connected in parallel with each other,
a number of multiple ones of the first switch is n corresponding to the n first tuning capacitors, and the first switches are connected in parallel with each other,
the first control circuit controls the operation of the n first switches individually, and
the second control circuit controls the operation of the n second switches individually.

16. The mobile apparatus of claim 15, wherein the tuned data storage section includes a latch circuit for storing first information on which one of the n first switches should be turned ON or OFF and second information on which one of the n second switches should be turned ON or OFF.

17. The mobile apparatus of claim 15, wherein the tuned data storage section includes a nonvolatile memory for storing first information on which one of the n first switches should be turned ON or OFF and second information on which one of the n second switches should be turned ON or OFF.

18. The mobile apparatus of claim 14, wherein at least the first tuning capacitor, the second tuning capacitor, the first switch, the second switch, the first control circuit, and the second control circuit are integrated on a same semiconductor substrate.

19. The mobile apparatus of claim 14, wherein the capacitor comprises: a first capacitor one electrode of which is connected to one end of the reception inductor and the first terminal and the other electrode of which is connected to the reference terminal, the first capacitor being connected in parallel with the first tuning capacitor; and a second capacitor one electrode of which is connected to the other end of the reception inductor and the second terminal and the other electrode of which is connected to the reference terminal, the second capacitor being connected in parallel with the second tuning capacitor.

20. The mobile apparatus of claim 14, wherein the detection circuit section includes: an output portion; a first diode whose anode is connected to the first terminal and whose cathode is connected to the output portion; and the second diode whose anode is connected to the second terminal and whose cathode is connected to the output portion.

21. The mobile apparatus of claim 20, wherein the detection circuit section further includes: a third diode whose anode is connected to the reference terminal and whose cathode is connected to the anode of the first diode and the first terminal; and a fourth diode whose anode is connected to the reference terminal and whose cathode is connected to the anode of the second diode and the second terminal, and
the first diode, the second diode, the third diode, and the fourth diode constitute a bridge rectifier circuit.

22. The mobile apparatus of claim 21, wherein the detection circuit section further includes: a comparator for comparing the potential of the first terminal with the potential of the second terminal; a third switch controlled with the output of the comparator for short-circuiting the anode and cathode of the first diode; and a fourth switch controlled with an inverted signal of the output of the comparator for short-circuiting the anode and cathode of the second diode.

23. The mobile apparatus of claim 14, wherein the capacitor is connected to one end of the reception inductor, the first terminal, and the second terminal at one electrode, and connected to the reference terminal and the other end of the reception inductor at the other electrode, and is connected in parallel with the first tuning capacitor and the second tuning capacitor.
